(19) United States
(12) Patent Application Publication
(10) Pub. No.: US 2015/0137187 A1
(43) Pub. Date: May 21, 2015

(54) SEMICONDUCTOR WAFER, MANUFACTURING METHOD OF SEMICONDUCTOR WAFER AND METHOD FOR MAUNFACTURING COMPOSITE WAFER

(71) Applicant: SUMITOMO CHEMICAL COMPANY, LIMITED, Tokyo (JP)

(72) Inventors: Takeshi AOKI, Ehime (JP); Osamu ICHIKAWA, Ibaraki (JP); Taketsugu YAMAMOTO, Ibaraki (JP)

(73) Assignee: SUMITOMO CHEMICAL COMPANY, LIMITED, Tokyo (JP)

(21) Appl. No.: 14/602,448

(22) Filed: Jan. 22, 2015

Related U.S. Application Data
(63) Continuation-in-part of application No. PCT/JP2013/004439, filed on Jul. 22, 2013.

(30) Foreign Application Priority Data
Jul. 24, 2012 (JP) 2012-164213

(51) Int. Cl. H01L 29/267; H01L 29/205; H01L 21/02; H01L 29/165

(52) U.S. Cl. CPC H01L 29/267; H01L 29/165; H01L 29/205; H01L 21/02532; H01L 21/02543; H01L 21/02546; H01L 21/02664
USPC 257/201; 257/200; 438/478; 438/458

(57) ABSTRACT

A semiconductor wafer comprises, on a semiconductor crystal layer forming wafer, a first semiconductor crystal layer, a second semiconductor crystal layer, and a third semiconductor crystal layer in this order, wherein both the etching rates of the first semiconductor crystal layer and the third semiconductor crystal layer by a first etching agent are higher than the etching rate of the second semiconductor crystal layer by the first etching agent, and both the etching rates of the first semiconductor crystal layer and the third semiconductor crystal layer by a second etching agent are lower than the etching rate of the second semiconductor crystal layer by the second etching agent.

The contents of the following patent applications are incorporated herein by reference:
NO. 2012-164213 filed in Japan on Jul. 24, 2012, and
NO. PCT/JP2013/004439 filed on Jul. 22, 2013.

### BACKGROUND

1. Technical Field

The present invention relates to a semiconductor wafer, a method for manufacturing a semiconductor wafer, and a method for manufacturing a composite wafer.

2. Related Art

Group III-V compound semiconductors such as GaAs, InGaAs and InP have high electron mobility. On the other hand, Group IV semiconductors such as Ge and SiGe have high hole mobility. Therefore, a highly advanced CMOSFET (complementary metal-oxide-semiconductor field effect transistor) can be realized if the Group III-V compound semiconductors are used to form an N-channel MOSFET (metal-oxide-semiconductor field effect transistor) (hereinafter, may be simply referred to as nMOSFET) and the Group IV semiconductors are used to form a P-channel MOSFET (hereinafter, may be simply referred to as “pMOSFET”). Non-Patent Document 1 discloses a CMOSFET structure in which an N-channel MOSFET having a channel made of a Group III-V compound semiconductor and a P-channel MOSFET having a channel made of Ge are formed on a single wafer.

To form heterogeneous materials of a Group III-V compound semiconductor crystal layer and a Group IV semiconductor crystal layer on a single wafer (for example, a silicon wafer), a technique is known to transfer onto the transfer target wafer a semiconductor crystal layer that has been formed on a semiconductor crystal growth wafer. For example, Non-Patent Document 2 discloses a technique according to which an AlAs layer is formed as a sacrificial layer on a GaAs wafer and a Ge layer is formed on the sacrificial layer (AlAs layer) and transferred onto a silicon wafer.
[Non-Patent Document 1] S. Takagi, et al., SSE, vol. 51, pp. 526-536, 2007.
[Non-Patent Document 2] Y. Bai and E. A. Fitzgerald, ECS Transactions, 33 (6) 927-932 (2010)

### SUMMARY

To form on a single wafer an N-channel MISFET (metal-insulator-semiconductor field effect transistor) (hereinafter, may be simply referred to as “nMISFET”) having a channel made of a Group III-V compound semiconductor and a P-channel MISFET (hereinafter, may be simply referred to as “pMISFET”) having a channel made of a Group IV semiconductor, it is necessary to develop a technique of forming the Group III-V compound semiconductor crystal layer for the n-MISFET and the Group IV semiconductor crystal layer for the p-MISFET on the single wafer. Furthermore, taking into consideration that the nMISFET and the pMISFET are manufactured as a LSI (large scale integration), a semiconductor crystal layer for an nMISFET or a pMISFET is preferably formed on a silicon wafer that allows utilization of existing manufacturing devices and existing steps. By using the technique of Non-Patent Document 2, a Group III-V compound semiconductor crystal layer and a Group IV semiconductor crystal layer can be formed on a single wafer, and these semiconductor crystal layers can be formed on a silicon wafer that is advantageous in terms of manufacturing.

However, in the technique of Non-Patent Document 2, a semiconductor crystal layer is separated from a semiconductor crystal layer forming wafer by etching and removing a sacrificial layer. Accordingly, when separating the semiconductor crystal layer, it is necessary to use an etching agent that has a high etching selection ratio of the sacrificial layer with respect to the etching selection ratio of the semiconductor crystal layer, that is, an etching agent that substantially does not etch away the semiconductor crystal layer, but provides a high etching rate of the sacrificial layer. Because it is assumed that a semiconductor crystal layer can be formed on the sacrificial layer by epitaxial growth, both of the requirements that the semiconductor crystal layer can be grown epitaxially, and that the etching selection ratio is sufficient need to be met, and depending on the material of the semiconductor crystal layer, selection of the sacrificial layer and the etching agent sometimes becomes difficult. In particular, when the semiconductor crystal layer is a Group III-V compound semiconductor, an electronic device is often created by using hetero-junction, and a semiconductor crystal layer is often a laminate including a plurality of layers. Because even in such a case, the requirement about the etching selection ratio of the sacrificial layer needs to be met with respect to all of the plurality of semiconductor crystal layers constituting the laminate, selection of the etching agent tends to become more difficult, and sometimes an appropriate etching agent does not exist.

An object of the present invention is to provide a technique that, when separating a semiconductor crystal layer from a wafer by using a sacrificial layer, allows selection of an appropriate combination of the sacrificial layer and an etching agent, irrespective of the material or structure of the semiconductor crystal layer.

In order to solve the problem, a first aspect of the present invention provides a semiconductor wafer comprising, on a semiconductor crystal layer forming wafer, a first semiconductor crystal layer, a second semiconductor crystal layer, and a third semiconductor crystal layer, the semiconductor crystal layer forming wafer, the first semiconductor crystal layer, the second semiconductor crystal layer, and the third semiconductor crystal layer being positioned in the order of the semiconductor crystal layer forming wafer, the first semiconductor crystal layer, the second semiconductor crystal layer, and the third semiconductor crystal layer, wherein both the etching rate of the first semiconductor crystal layer by a first etching agent and the etching rate of the third semiconductor crystal layer by the first etching agent are higher than the etching rate of the second semiconductor crystal layer by the first etching agent, and both the etching rate of the first semiconductor crystal layer by a second etching agent and the etching rate of the third semiconductor crystal layer by the second etching agent are lower than the etching rate of the second semiconductor crystal layer by the second etching agent.

The semiconductor wafer may further comprise a fourth semiconductor crystal layer, the semiconductor crystal layer forming wafer, the first semiconductor crystal layer, the second semiconductor crystal layer, the third semiconductor crystal layer, and the fourth semiconductor crystal layer being positioned in the order of the semiconductor crystal layer forming wafer, the first semiconductor crystal layer, the second semiconductor crystal layer, the third semiconductor crystal layer, and the fourth semiconductor crystal layer, wherein both the etching rate of the first semiconductor crystal layer by the first etching agent and the etching rate of the third semiconductor crystal layer by the first etching agent may be higher than the etching rate of the fourth semiconductor crystal layer by the first etching agent, and both the etching rate of the first semiconductor crystal layer by the second etching agent and the etching rate of the third semiconductor crystal layer by the second etching agent may be lower than the etching rate of the fourth semiconductor crystal layer by the second etching agent. The etching rate of the semiconductor crystal layer forming wafer by the first etching agent may be equivalent to the etching rate of the second semiconductor crystal layer by the first etching agent, and the etching rate of the semiconductor crystal layer forming wafer by the second etching agent may be equivalent to the etching rate of the second semiconductor crystal layer by the second etching agent.

The semiconductor crystal layer forming wafer may be made of InP, the first semiconductor crystal layer and the third semiconductor crystal layer may be made of InGaAs or InAs, and the second semiconductor crystal layer is made of InP. In this case, when the semiconductor wafer further comprises the fourth semiconductor crystal layer, the fourth semiconductor crystal layer may be made of InP. The third semiconductor crystal layer may have a semiconductor laminate structure, and the semiconductor laminate structure preferably consists of a plurality of semiconductor layers that lattice-match or pseudo-lattice-match InP.

When the semiconductor crystal layer forming wafer is made of GaAs or Ge, the first semiconductor crystal layer and the third semiconductor crystal layer are made of SiGe, and the second semiconductor crystal layer is made of Ge. In this case, when the semiconductor wafer further comprises the fourth semiconductor crystal layer, the fourth semiconductor crystal layer may be made of Ge.

A second aspect of the present invention provides a method for manufacturing a semiconductor wafer comprising forming, on a semiconductor crystal layer forming wafer, a first semiconductor crystal layer, a second semiconductor crystal layer, and a third semiconductor crystal layer in the order of the first semiconductor crystal layer, the second semiconductor crystal layer, and the third semiconductor crystal layer by epitaxial growth, wherein the first semiconductor crystal layer, the second semiconductor crystal layer, and the third semiconductor crystal layer are such that both the etching rate of the first semiconductor crystal layer by a first etching agent and the etching rate of the third semiconductor crystal layer by the first etching agent are higher than the etching rate of the second semiconductor crystal layer by the first etching agent, and both the etching rate of the first semiconductor crystal layer by a second etching agent and the etching rate of the third semiconductor crystal layer by the second etching agent are lower than the etching rate of the second semiconductor crystal layer by the second etching agent.

A third aspect of the present invention provides a method for manufacturing a semiconductor wafer comprising forming, on a semiconductor crystal layer forming wafer, a first semiconductor crystal layer, a second semiconductor crystal layer, a third semiconductor crystal layer, and a fourth semiconductor crystal layer in the order of the first semiconductor crystal layer, the second semiconductor crystal layer, the third semiconductor crystal layer, and the fourth semiconductor crystal layer by epitaxial growth, wherein the first semiconductor crystal layer, the second semiconductor crystal layer, the third semiconductor crystal layer, and the fourth semiconductor crystal layer are such that both the etching rate of the first semiconductor crystal layer by a first etching agent and the etching rate of the third semiconductor crystal layer by the first etching agent are higher than both the etching rate of the second semiconductor crystal layer by the first etching agent and the etching rate of the fourth semiconductor crystal layer by the first etching agent, and both the etching rate of the first semiconductor crystal layer by a second etching agent and the etching rate of the third semiconductor crystal layer by the second etching agent are lower than both the etching rate of the second semiconductor crystal layer by the second etching agent and the etching rate of the fourth semiconductor crystal layer by the second etching agent.

A fourth aspect of the present invention provides a method for manufacturing a composite wafer, the method comprising: forming a pattern of a first cover layer on the above-described semiconductor wafer; performing first etching to etch away the third semiconductor crystal layer by using the first cover layer as a mask; forming a pattern of a second cover layer to cover the third semiconductor crystal layer patterned by the first etching; performing second etching to etch away the second semiconductor crystal layer by using the second cover layer as a mask and by using the second etching agent; and removing the first semiconductor crystal layer by performing etching by using the first etching agent, and separating, from the semiconductor crystal layer forming wafer, the second semiconductor crystal layer and the third semiconductor crystal layer that are covered with the second cover layer. The first etching may include etching away the third semiconductor crystal layer by using the first etching agent.

A fifth aspect of the present invention provides a method for manufacturing a composite wafer, the method comprising: forming a pattern of a first cover layer on the above-described semiconductor wafer; performing first etching to etch away the third semiconductor crystal layer by using the first cover layer as a mask; performing second etching to etch away the second semiconductor crystal layer by using, as a mask, the first cover layer or the third semiconductor crystal layer patterned in the first etching and using the second etching agent; forming a pattern of a third cover layer to cover the third semiconductor crystal layer patterned in the first etching and the second semiconductor crystal layer patterned in the second etching; and removing the first semiconductor crystal layer by performing etching by using the first etching agent, and separating, from the semiconductor crystal layer forming wafer, the second semiconductor crystal layer and the third semiconductor crystal layer that are covered with the third cover layer. The first etching may include etching away the third semiconductor crystal layer by using the first etching agent.

A sixth aspect of the present invention provides a method for manufacturing a composite wafer, the method comprising: forming a pattern of a first cover layer on the above-described semiconductor wafer having the fourth semiconductor crystal layer; performing first etching to etch away the fourth semiconductor crystal layer by using the first cover layer as a mask; performing second etching to etch away the third semiconductor crystal layer by using, as a mask, the first cover layer or the fourth semiconductor crystal layer patterned by the first etching; forming a pattern of a fourth cover layer to cover the fourth semiconductor crystal layer patterned in the first etching and the third semiconductor crystal layer patterned in the second etching; performing third etching to etch away the second semiconductor crystal layer by using the fourth cover layer as a mask and by using the second etching agent; and removing the first semiconductor crystal layer by performing etching by using the first etching agent, and separating, from the semiconductor crystal layer forming wafer, the second semiconductor crystal layer, the third semiconductor crystal layer, and the fourth semiconductor crystal layer that are covered with the fourth cover layer. The first etching may include etching away the fourth semiconductor crystal layer by using the second etching agent, and the second etching may include etching away the third semiconductor crystal layer by using the first etching agent

A seventh aspect of the present invention provides a method for manufacturing a composite wafer, the method comprising: forming a pattern of a first cover layer on the above-described semiconductor wafer having the fourth semiconductor crystal layer; performing first etching to etch away the fourth semiconductor crystal layer and the third semiconductor crystal layer by using the first cover layer as a mask and to further etch away the second semiconductor crystal layer by using the second etching agent; forming a pattern of a fifth cover layer to cover the fourth semiconductor crystal layer, the third semiconductor crystal layer, and the second semiconductor crystal layer that are patterned in the first etching; and removing the first semiconductor crystal layer by performing etching by using the first etching agent, and separating, from the semiconductor crystal layer forming wafer, the second semiconductor crystal layer, the third semiconductor crystal layer, and the fourth semiconductor crystal layer that are covered with the fifth cover layer.

In each of the fourth to seventh aspects, the second cover layer, the third layer, the fourth layer, and the fifth layer may respectively cover the third semiconductor crystal layer or the like depending their aspects, and may cover the back surface and side surface of the semiconductor crystal layer forming wafer.

In each of the fourth to seventh aspects, the further may further comprise: prior to the separation, bonding the semiconductor wafer and a transfer target wafer, with the front surface of the semiconductor wafer on which the third semiconductor crystal layer is formed being caused to face the front surface of the transfer target wafer; and during the separation, separating the semiconductor wafer and the transfer target wafer in a state that a semiconductor crystal layer including the second semiconductor crystal layer and the third semiconductor crystal layer is left on the transfer target wafer.

An eighth aspect of the present invention provides a method for manufacturing a composite wafer, the method comprising: forming a sixth cover layer to cover the above-described entire surface of the semiconductor wafer; patterning and removing a part of the sixth cover layer on the third semiconductor crystal layer; etching away the third semiconductor crystal layer by using the sixth cover layer on the third semiconductor crystal layer as a mask; and removing the second semiconductor crystal layer by performing etching by using the second etching agent, and separating the third semiconductor crystal layer from the semiconductor crystal layer forming wafer that is covered with the sixth cover layer and the first semiconductor crystal layer.

The method may further comprise: after etching away the third semiconductor crystal layer and prior to the separation, bonding the semiconductor wafer and a transfer target wafer, with the front surface of the third semiconductor crystal layer being caused to face the front surface of the transfer target wafer; and during the separation, separating the semiconductor wafer and the transfer target wafer in a state that the third semiconductor crystal layer is left on the transfer target wafer. The method may further comprise, after etching away the third semiconductor crystal layer and prior to the bonding, etching away the second semiconductor crystal layer by using the sixth cover layer as a mask and by using the second etching agent.

A ninth aspect of the present invention provides a method for manufacturing a composite wafer by using a semiconductor wafer having, on a semiconductor crystal layer forming wafer, a first semiconductor crystal layer, a second semiconductor crystal layer, and a third semiconductor crystal layer, the semiconductor crystal layer forming wafer, the first semiconductor crystal layer, the second semiconductor crystal layer, and the third semiconductor crystal layer being positioned in the order of the semiconductor crystal layer forming wafer, the first semiconductor crystal layer, the second semiconductor crystal layer, and the third semiconductor crystal layer, both the etching rate of the semiconductor crystal layer forming wafer by a second etching agent and the etching rate of the second semiconductor crystal layer by the second etching agent being higher than both the etching rate of the first semiconductor crystal layer by the second etching agent and the etching rate of the third semiconductor crystal layer by the second etching agent, the method comprising forming a sixth cover layer to cover the entire surface of the semiconductor wafer; patterning and removing a part of the sixth cover layer on the third semiconductor crystal layer; etching away the third semiconductor crystal layer by using the sixth cover layer on the third semiconductor crystal layer as a mask; and removing the second semiconductor crystal layer by performing etching by using the second etching agent, and separating the third semiconductor crystal layer from the semiconductor crystal layer forming wafer that is covered with the sixth cover layer and the first semiconductor crystal layer.

The summary clause does not necessarily describe all necessary features of the embodiments of the present invention. The present invention may also be a sub-combination of the features described above.

### BRIEF DESCRIPTION OF THE DRAWINGS

FIG. 1 is a cross-sectional view illustrating a semiconductor wafer 100.

FIG. 2 is a cross-sectional view illustrating, in the order of steps, one example of a method for manufacturing a composite wafer by using the semiconductor wafer 100.

FIG. 3 is a cross-sectional view illustrating, in the order of steps, one example of a method for manufacturing a composite wafer by using the semiconductor wafer 100.

FIG. 4 is a cross-sectional view illustrating, in the order of steps, one example of a method for manufacturing a composite wafer by using the semiconductor wafer 100.

FIG. 5 is a cross-sectional view illustrating, in the order of steps, one example of a method for manufacturing a composite wafer by using the semiconductor wafer 100.

FIG. 6 is a cross-sectional view illustrating, in the order of steps, one example of a method for manufacturing a composite wafer by using the semiconductor wafer 100.

FIG. 7 is a cross-sectional view illustrating, in the order of steps, a variant of one example of a method for manufacturing a composite wafer by using the semiconductor wafer 100.

FIG. 8 is a cross-sectional view illustrating, in the order of steps, a variant of one example of a method for manufacturing a composite wafer by using the semiconductor wafer 100.

FIG. 9 is a cross-sectional view illustrating, in the order of steps, another example of a method for manufacturing a composite wafer by using the semiconductor wafer 100.

FIG. 10 is a cross-sectional view illustrating, in the order of steps, another example of a method for manufacturing a composite wafer by using the semiconductor wafer 100.

FIG. 11 is a cross-sectional view illustrating, in the order of steps, another example of a method for manufacturing a composite wafer by using the semiconductor wafer 100.

FIG. 12 is a cross-sectional view illustrating a semiconductor wafer 200.

FIG. 13 is a cross-sectional view illustrating, in the order of steps, one example of a method for manufacturing a composite wafer by using the semiconductor wafer 200.

FIG. 14 is a cross-sectional view illustrating, in the order of steps, one example of a method for manufacturing a composite wafer by using the semiconductor wafer 200.

FIG. 15 is a cross-sectional view illustrating, in the order of steps, one example of a method for manufacturing a composite wafer by using the semiconductor wafer 200.

FIG. 16 is a cross-sectional view illustrating, in the order of steps, one example of a method for manufacturing a composite wafer by using the semiconductor wafer 200.

FIG. 17 is a cross-sectional view illustrating, in the order of steps, one example of a method for manufacturing a composite wafer by using the semiconductor wafer 200.

FIG. 18 is a cross-sectional view illustrating, in the order of steps, one example of a method for manufacturing a composite wafer by using the semiconductor wafer 200.

FIG. 19 is a cross-sectional view illustrating, in the order of steps, another example of a method for manufacturing a composite wafer by using the semiconductor wafer 200.

FIG. 20 is a cross-sectional view illustrating, in the order of steps, another example of a method for manufacturing a composite wafer by using the semiconductor wafer 200.

FIG. 21 is a cross-sectional view illustrating, in the order of steps, another example of a method for manufacturing a composite wafer by using the semiconductor wafer 200.

FIG. 22 is a cross-sectional view illustrating, in the order of steps, still another example of a method for manufacturing a composite wafer by using the semiconductor wafer 200.

FIG. 23 is a cross-sectional view illustrating, in the order of steps, still another example of a method for manufacturing a composite wafer by using the semiconductor wafer 200.

FIG. 24 is a cross-sectional view illustrating, in the order of steps, still another example of a method for manufacturing a composite wafer by using the semiconductor wafer 200.

FIG. 25 is a cross-sectional view illustrating, in the order of steps, still another example of a method for manufacturing a composite wafer by using the semiconductor wafer 200.

FIG. 26 is a cross-sectional view illustrating, in the order of steps, still another example of a method for manufacturing a composite wafer by using the semiconductor wafer 100.

FIG. 27 is a cross-sectional view illustrating, in the order of steps, still another example of a method for manufacturing a composite wafer by using the semiconductor wafer 100.

FIG. 28 is a cross-sectional view illustrating, in the order of steps, still another example of a method for manufacturing a composite wafer by using the semiconductor wafer 100.

FIG. 29 is a cross-sectional view illustrating, in the order of steps, still another example of a method for manufacturing a composite wafer by using the semiconductor wafer 100.

FIG. 30 is a cross-sectional view illustrating, in the order of steps, still another example of a method for manufacturing a composite wafer by using the semiconductor wafer 100.

### DESCRIPTION OF EXEMPLARY EMBODIMENTS

Hereinafter, (some) embodiment(s) of the present invention will be described. The embodiment(s) do(es) not limit the invention according to the claims, and all the combinations of the features described in the embodiment(s) are not necessarily essential to means provided by aspects of the invention.

### First Embodiment

FIG. 1 is a cross-sectional view illustrating a semiconductor wafer 100. The semiconductor wafer 100 has, on a semiconductor crystal layer forming wafer 102, a first semiconductor crystal layer 104, a second semiconductor crystal layer 106, and a third semiconductor crystal layer 108. The semiconductor crystal layer forming wafer 102, the first semiconductor crystal layer 104, the second semiconductor crystal layer 106, and the third semiconductor crystal layer 108 are positioned in the order of the semiconductor crystal layer forming wafer 102, the first semiconductor crystal layer 104, the second semiconductor crystal layer 106, and the third semiconductor crystal layer 108. The first semiconductor crystal layer 104 is a layer to serve as a sacrificial layer, the second semiconductor crystal layer 106 is a layer to serve as an etching stopper, and the third semiconductor crystal layer 108 is a layer to be transferred and to be utilized as an active layer and the like of a semiconductor device.

The semiconductor crystal layer forming wafer 102 is a wafer for forming a high quality third semiconductor crystal layer 108. A preferred material for the semiconductor crystal layer forming wafer 102 depends on the material, formation method, and the like of the third semiconductor crystal layer 108. In general, the semiconductor crystal layer forming wafer 102 is desirably made of a material that lattice-matches or pseudo-lattice-matches the third semiconductor crystal layer 108 to be formed. For example, when an InP layer is formed as the third semiconductor crystal layer 108 by epitaxial growth, the semiconductor crystal layer forming wafer 102 is preferably an InP single crystal wafer, and a GaAs wafer, a Si wafer, or the like can be selected. For example, a GaAs layer or a Ge layer is formed as the third semiconductor crystal layer 108 by epitaxial growth, the semiconductor crystal layer forming wafer 102 is preferably a GaAs single crystal wafer, and a single crystal wafer of InP, sapphire Ge, or SiC can be selected. When the semiconductor crystal layer forming wafer 102 is a GaAs single crystal wafer or an InP single crystal wafer, the plane on which the third semiconductor crystal layer 108 is formed may be the (100) plane or (111) plane.

The first semiconductor crystal layer 104 is a sacrificial layer for separating the semiconductor crystal layer forming wafer 102 from the second semiconductor crystal layer 106 and the third semiconductor crystal layer 108. When the first semiconductor crystal layer 104 is removed by etching, the semiconductor crystal layer forming wafer 102 is separated from the second semiconductor crystal layer 106 and the third semiconductor crystal layer 108. When an InP single crystal wafer is selected as the semiconductor crystal layer forming wafer 102, and an InP layer is selected as the second semiconductor crystal layer 106, an InGaAs layer or an InAs layer can be selected as the first semiconductor crystal layer 104, and an InAs layer or an InₓGa₁₋ₓAs layer (1>x>0.53) is preferable. When a GaAs single crystal wafer or a Ge single crystal wafer is selected as the semiconductor crystal layer forming wafer 102, and a Ge layer is selected as the second semiconductor crystal layer 106, the first semiconductor crystal layer 104 is preferably a SiGe layer. When a GaAs single crystal wafer is selected as the semiconductor crystal layer forming wafer 102, and a GaAs layer is selected as the second semiconductor crystal layer 106, the first semiconductor crystal layer 104 is preferably an AlAs layer, and an InAlAs layer, an InGap layer, an InAlP layer, an InGaAlP layer, or an AlSb layer can be selected. Because as the thickness of the first semiconductor crystal layer 104 becomes larger, the crystallinity of the third semiconductor crystal layer 108 tends to be lower, the thickness of the first semiconductor crystal layer 104 is preferably as small as possible as long as the functionality as a sacrificial layer can be ensured. The thickness of the first semiconductor crystal layer 104 can be selected from within the range of 0.1 nm to 10 μm.

The second semiconductor crystal layer 106 is an etching stopper layer to be used when etching away the first semiconductor crystal layer 104 which is a sacrificial layer. The second semiconductor crystal layer 106 suffices as long as the etching selection ratio with respect to the first semiconductor crystal layer 104 is ensured. Specific examples of the second semiconductor crystal layer 106 include, as exemplified above, an InP layer, a Ge layer, and a GaAs layer. Because as the thickness of the second semiconductor crystal layer 106 becomes larger, the crystallinity of the third semiconductor crystal layer 108 tends to be lower, the thickness of the second semiconductor crystal layer 106 is preferably as small as possible as long as the functionality as an etching stopper layer can be ensured. In the present example, the functionality of the etching stopper layer is to protect the third semiconductor crystal layer 108 when etching away the first semiconductor crystal layer 104. The thickness of the second semiconductor crystal layer 106 can be selected from within the range of 0.1 nm to 10 μm.

The third semiconductor crystal layer 108 is a transfer layer that is to be separated from the semiconductor crystal layer forming wafer 102 when the first semiconductor crystal layer 104 is etched away and to be transferred onto a transfer target wafer or the like. The third semiconductor crystal layer 108 is utilized for an active layer or the like of a semiconductor device. When the third semiconductor crystal layer 108 is formed on the semiconductor crystal layer forming wafer 102 by epitaxial growth or the like, high quality crystallinity of the third semiconductor crystal layer 108 is realized. Furthermore, when the third semiconductor crystal layer 108 is transferred onto a transfer target wafer, it becomes possible to form the third semiconductor crystal layer 108 on a given transfer target wafer without considering lattice-matching and the like with the transfer target wafer.

Examples of the third semiconductor crystal layer 108 include a crystal layer made of a Group III-V compound semiconductor, a crystal layer made of a Group IV semiconductor, and a crystal layer made of a Group II-VI compound semiconductor. Examples of the Group III-V compound semiconductor include AlᵤGaᵥIn₁₋ᵤ₋ᵥNₘPₙAs_{q}Sb_{1-m-n-q} (0≦u≦1, 0≦v≦1, 0≦m≦1, 0≦n≦1, 0≦q≦1), for example, GaAs, In_{y}Ga_{1-y}As (0<y<1), InP and GaSb. Examples of the Group IV semiconductor include Ge and GeₓSi₁₋ₓ (0<x<1). Examples of the Group II-VI compound semiconductor is ZnO, ZnSe, ZnTe, CdS, CdSe, and CdTe. When the Group IV semiconductor is GeₓSi₁₋ₓ, the Ge ratio x is preferably equal to or higher than 0.9. When the Ge ratio x is equal to or higher than 0.9, the Group IV semiconductor can have similar semiconductor characteristics to Ge. If the third semiconductor crystal layer 108 is one of the above-described crystal layers and laminate, the third semiconductor crystal layer 108 can be used to form an active layer of a field effect transistor with high mobility, in particular, of a complementary field effect transistor having high mobility.

The third semiconductor crystal layer 108 is not limited to those exemplified above, but a semiconductor layer other than those exemplified is also applicable. Also, the third semiconductor crystal layer 108 may be a semiconductor laminate in which a plurality of types of semiconductor layers are laminated. Examples of a structure of a semiconductor laminate obtained in the present invention include, for example, a HEMT (High Electron Mobility Transistor) structure having a AlGaAs buffer layer, an n-type AlGaAs electron introducing layer, an InₓGa₁₋ₓAs (0<x≦0.4) channel layer, an n-type AlGaAs electron introducing layer, and an n-type AlGaAs contact layer. Also, examples of a structure of a semiconductor laminate obtained in the present invention include a HBT (Heterojunction Bipolar Transistor) structure having a p-type GaAs base layer, an n-type GaAs contact layer, and an n-type InGaP emitter layer. Also, examples of a structure of a semiconductor laminate obtained in the present invention include a MESFET (Metal-Semiconductor Field Effect Transistor) structure, a VCSEL (Vertical Cavity Surface Emitting LASER) structure, a red LED (Light Emitting Diode) structure, a semiconductor laser structure, a photodiode structure, and a solar cell structure. Note that the structures listed here are examples, and the present invention can be applied to device structures in general that use Group III-V compound hetero-junction.

The thickness of the third semiconductor crystal layer 108 can be appropriately selected from within the range of 0.1 nm to 500 μm. The thickness of the third semiconductor crystal layer 108 is preferably no less than 0.1 nm and less than 1 μm. When the third semiconductor crystal layer 108 is less than 1 μm, for example, it can be used for a composite wafer suited to manufacturing of a high performance transistor such as a ultrathin-body MISFET.

To cause the first semiconductor crystal layer 104 to serve as a sacrificial layer, cause the second semiconductor crystal layer 106 to serve as an etching stopper layer, and separate the third semiconductor crystal layer 108 from the semiconductor crystal layer forming wafer 102, the relationship among the etching rates of the semiconductor crystal layer forming wafer 102, the first semiconductor crystal layer 104, the second semiconductor crystal layer 106, and the third semiconductor crystal layer 108 are required to meet the following conditions. That is, both the etching rate of the first semiconductor crystal layer 104 by a first etching agent and the etching rate of the third semiconductor crystal layer 108 by the first etching agent are higher than the etching rate of the second semiconductor crystal layer 106 by the first etching agent. Also, both the etching rate of the first semiconductor crystal layer 104 by a second etching agent and the etching rate of the third semiconductor crystal layer 108 by the second etching agent are lower than the etching rate of the second semiconductor crystal layer 106 by the second etching agent. When the etching rates have the relationship like these, in a method for manufacturing a composite wafer described below, it is possible to cause the first semiconductor crystal layer 104 to serve as a sacrificial layer, cause the second semiconductor crystal layer 106 to serve as an etching stopper layer, and separate the third semiconductor crystal layer 108 from the semiconductor crystal layer forming wafer 102.

Note that the etching rate of the semiconductor crystal layer forming wafer 102 by the first etching agent may be equivalent to the etching rate of the second semiconductor crystal layer 106 by the first etching agent. Also, the etching rate of the semiconductor crystal layer forming wafer 102 by the second etching agent may be equivalent to the etching rate of the second semiconductor crystal layer 106 by the second etching agent. The “etching agent” includes both an “etching solution” and “etching gas”. That is, etching in the present specification includes both wet etching and dry etching.

Also, the semiconductor crystal layer forming wafer 102 may be made of InP, the first semiconductor crystal layer 104 and the third semiconductor crystal layer 108 may be made of InGaAs or InAs, and the second semiconductor crystal layer 106 may be made of InP. InGaAs or InAs used for the first semiconductor crystal layer 104 or the third semiconductor crystal layer 108 lattice-matches InP. When InGaAs is used, it is preferably InₓGa₁₋ₓAs (1>x>0.53). The semiconductor crystal layer forming wafer 102 may be made of GaAs or Ge, the first semiconductor crystal layer 104 and the third semiconductor crystal layer 108 may be made of SiGe, and the second semiconductor crystal layer 106 may be made of Ge.

When the semiconductor crystal layer forming wafer 102 is an InP single crystal wafer, the third semiconductor crystal layer 108 may have a semiconductor laminate structure. In this case, the semiconductor laminate structure is preferably made of a plurality of semiconductor layers that lattice-match or pseudo-lattice-match InP. The semiconductor laminate structure may constitute a quantum well. Also, the semiconductor laminate structure may be a strained super lattice structure that is designed to have a lattice constant that gradually increases or decreases in the thickness direction of the third semiconductor crystal layer 108. In this case, even when a crystal layer is formed on the third semiconductor crystal layer 108, it becomes unnecessary to cause the crystal layer to lattice-match or pseudo-lattice-match InP.

The first semiconductor crystal layer 104, the second semiconductor crystal layer 106, and the third semiconductor crystal layer 108 are formed sequentially on the semiconductor crystal layer forming wafer 102 by epitaxial growth, CVD (Chemical Vapor Deposition), sputtering, or ALD (Atomic Layer Deposition). Epitaxial growth may be MOCVD (Metal Organic Chemical Vapor Deposition), or MBE (Molecular Beam Epitaxy). When a Group III-V compound semiconductor crystal layer is formed as the first semiconductor crystal layer 104, the second semiconductor crystal layer 106, or the third semiconductor crystal layer 108 by MOCVD, TMGa (trimethylgallium), TMA (trimethylaluminum), TMIn (trimethylindium), AsH₃ (arsine), PH₃ (phosphine), or the like may be used as the source gas. When a Group IV semiconductor crystal layer is formed as the first semiconductor crystal layer 104, the second semiconductor crystal layer 106, or the third semiconductor crystal layer 108 by CVD, GeH₄ (germane), SiH₄ (silane), Si₂H₆ (disilane), or the like may be used as the source gas. Hydrogen may be used as the carrier gas. A compound in which a part of a plurality of hydrogen atom groups of the source gas is substituted with a chlorine atom or a hydrocarbon group may be used. The reaction temperature may be appropriately selected from within the range of 300° C. to 900° C. and preferably within the range of 400 to 800° C. By appropriately selecting the source gas flow rate or the reaction duration, the thickness of the first semiconductor crystal layer 104, the second semiconductor crystal layer 106, or the third semiconductor crystal layer 108 can be controlled.

### Second Embodiment

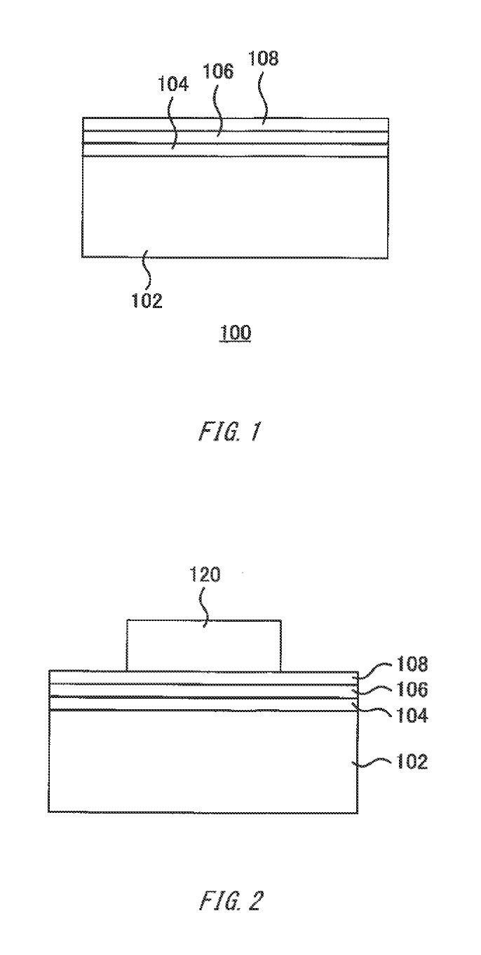

FIGS. 2 to 6 are cross-sectional views illustrating, in the order of steps, one example of a method for manufacturing a composite wafer by using the semiconductor wafer 100. The method for manufacturing a composite wafer in the present second embodiment uses the semiconductor wafer 100 described in the first embodiment.

As illustrated in FIG. 2, a pattern of a first cover layer 120 is formed on the semiconductor wafer 100. The third semiconductor crystal layer 108 located under the first cover layer 120 is to be transferred onto a transfer target wafer described below. The first cover layer 120 may either be an inorganic material or an organic material. Examples of the inorganic material include Al₂O₃, SiO₂, SiN, and ZrO₂. Examples of the organic material include photoresist, wax (Apiezon-W, etc.), and silicon rubber (PDMS, etc.). An inorganic material first cover layer 120 may be formed by atomic layer deposition (ALD) or CVD. Considering the advantages in step coverage, ALD is desired. An organic material first cover layer 120 may be formed by spin coating or the like. The pattern of the first cover layer 120 may be formed into any shape by using photoresist and lithography.

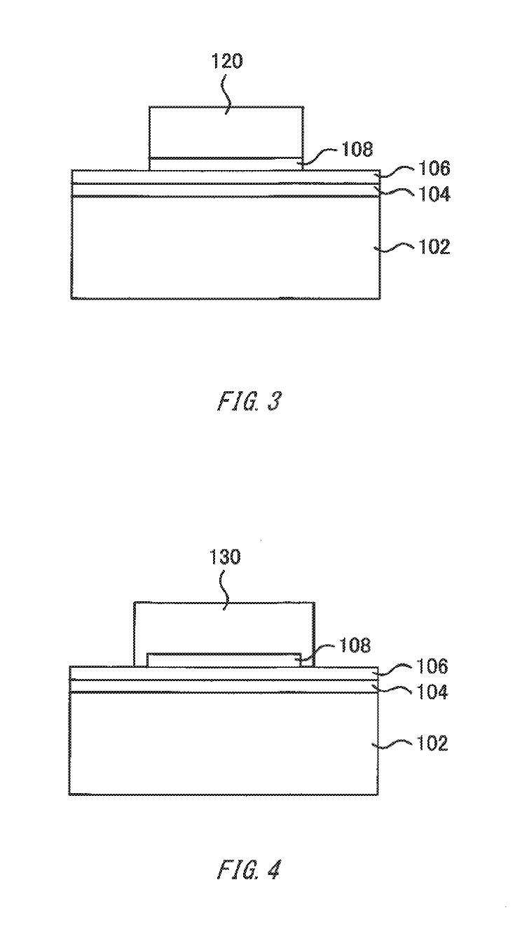

Next, as illustrated in FIG. 3, the third semiconductor crystal layer 108 is etched away by using the first cover layer 120 as a mask and by using the first etching agent (first etching step). When the third semiconductor crystal layer 108 is In_{0.53}Ga_{0.47}As, examples of the first etching agent include a solution containing phosphoric acid and hydrogen peroxide.

Next, as illustrated in FIG. 4, a pattern of a second cover layer 130 to cover the third semiconductor crystal layer 108 that has been patterned in the first etching step is formed. The second cover layer 130 in the present example covers the front surface and side surface of the third semiconductor crystal layer 108. The end portion of the second cover layer 130 covering the side surface of the third semiconductor crystal layer 108 contacts the second semiconductor crystal layer 106. That is, the entire surface of the third semiconductor crystal layer 108 is covered with the second cover layer 130 and the second semiconductor crystal layer 106. The material and formation method of the second cover layer 130 are similar to those of the first cover layer 120. The first cover layer 120 may be or may not be removed before the formation of the second cover layer 130. When the first cover layer 120 is not removed, the entire surface of the third semiconductor crystal layer 108 is covered with the first cover layer 120, the second cover layer 130, and the second semiconductor crystal layer 106.

Next, as illustrated in FIG. 5, the second semiconductor crystal layer 106 is etched away by using the second cover layer 130 as a mask and by using the second etching agent (second etching step). When the second semiconductor crystal layer 106 is InP, examples of the second etching agent include hydrochloric acid solution.

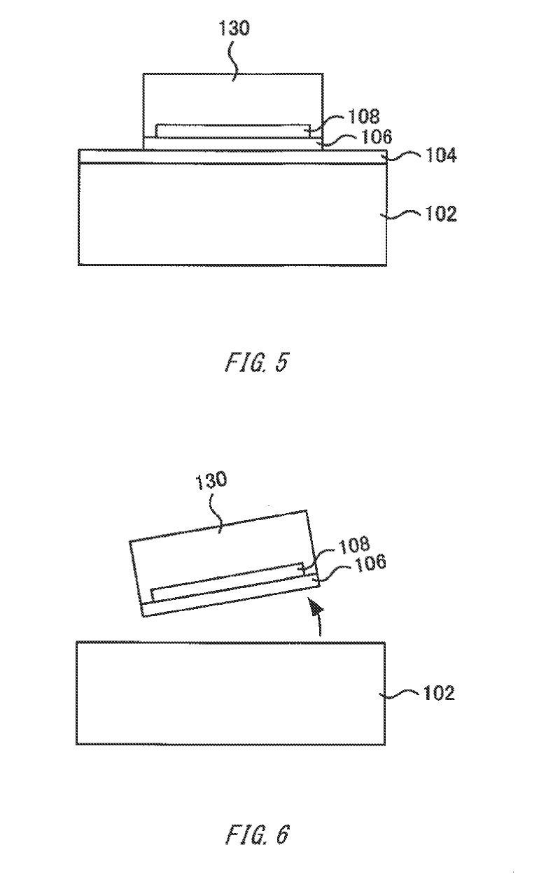

Lastly, as illustrated in FIG. 6, the first semiconductor crystal layer 104 is removed by performing etching by using the first etching agent, and the second semiconductor crystal layer 106 and the third semiconductor crystal layer 108 that are covered with the second cover layer 130 are separated from the semiconductor crystal layer forming wafer 102.

In the method for manufacturing a composite wafer in the present second embodiment, when the third semiconductor crystal layer 108 is to be separated from the semiconductor crystal layer forming wafer 102, the third semiconductor crystal layer 108 is surrounded by the second cover layer 130 and the second semiconductor crystal layer 106, and thus is never exposed to the first etching agent. Accordingly, a material that is similar to that of the first semiconductor crystal layer 104 can be used as the third semiconductor crystal layer 108, and an etching agent (first etching agent) can be selected without being limited by the material of the third semiconductor crystal layer 108 to be utilized as an active layer. Accordingly, the degree of freedom of manufacturing a composite wafer is enhanced, and the manufacturing becomes easy. Note that the etching agent used in etching of the third semiconductor crystal layer 108 may not be the first etching agent.

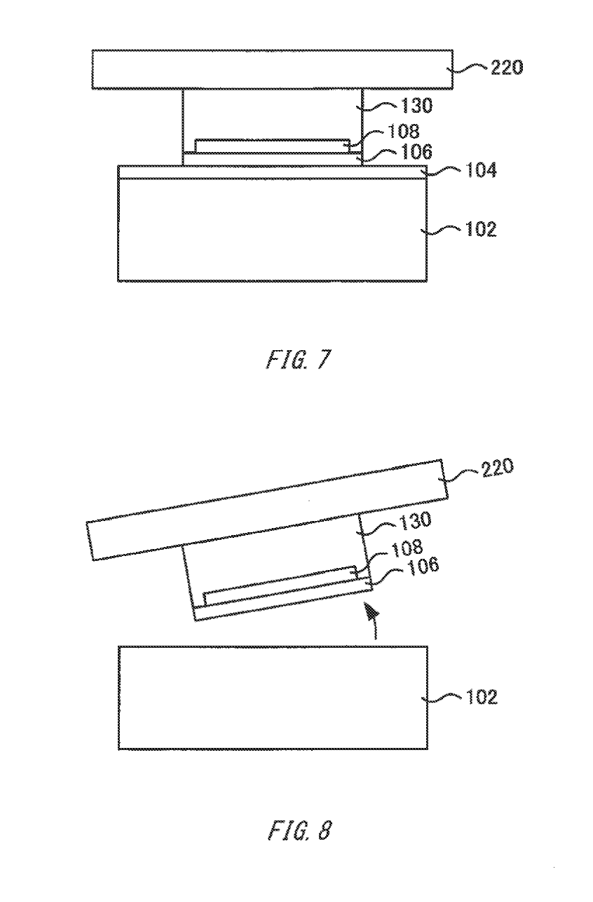

Note that, after the step illustrated in FIG. 5, the second cover layer 130 may be bonded to the transfer target wafer 220 as illustrated in FIG. 7, and the third semiconductor crystal layer 108 may be separated from the semiconductor crystal layer forming wafer 102 as illustrated in FIG. 8. In this case, because the separated third semiconductor crystal layer 108 (including the second cover layer 130 and the second semiconductor crystal layer 106) is attached to the transfer target wafer 220, it becomes easy to collect it.

### Third Embodiment

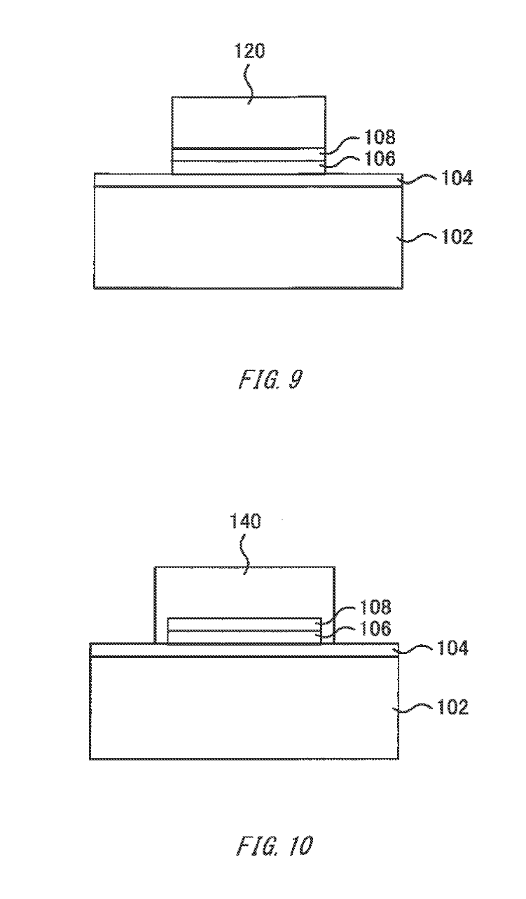

FIGS. 9 to 11 are cross-sectional views illustrating, in the order of steps, another example of a method for manufacturing a composite wafer by using the semiconductor wafer 100. The third embodiment is similar to the second embodiment up until the pattern of the first cover layer 120 is formed on the semiconductor wafer 100, and the third semiconductor crystal layer 108 is etched away by using the first cover layer 120 as a mask, and using the first etching agent (first etching step).

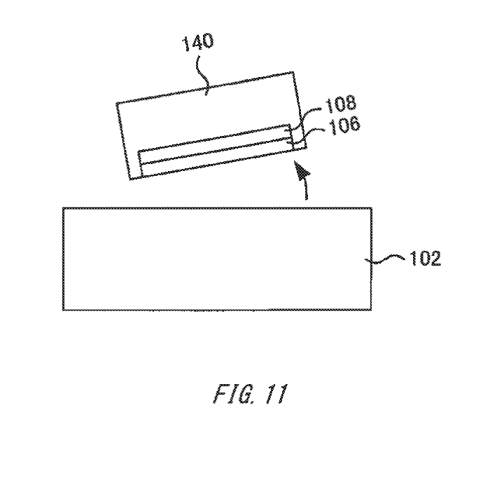

Next, as illustrated in FIG. 9, the second semiconductor crystal layer 106 is etched away by using, as a mask, the first cover layer 120 or the third semiconductor crystal layer 108 that has been patterned in the first etching step, and using the second etching agent (second etching step). Next, as illustrated in FIG. 10, a pattern of a third cover layer 140 to cover the third semiconductor crystal layer 108 that has been patterned in the first etching step and the second semiconductor crystal layer 106 that has been patterned in the second etching step is formed. The third cover layer 140 in the present example covers the front surface and side surface of the third semiconductor crystal layer 108, and the side surface of the second semiconductor crystal layer 106. The end portion of the third cover layer 140 covering the side surfaces of the second semiconductor crystal layer 106 and the third semiconductor crystal layer 108 contacts the first semiconductor crystal layer 104. The material and formation method of the third cover layer 140 are similar to those of the first cover layer 120. Furthermore, as illustrated in FIG. 11, the first semiconductor crystal layer 104 is removed by performing etching by using the first etching agent, and the second semiconductor crystal layer 106 and the third semiconductor crystal layer 108 that are covered with the third cover layer 140 are separated from the semiconductor crystal layer forming wafer 102.

Effects similar to those of the second embodiment can be attained in the method for manufacturing a composite wafer like this. Note that as in the second embodiment, the transfer target wafer 220 can be applied to the third embodiment.

### Fourth Embodiment

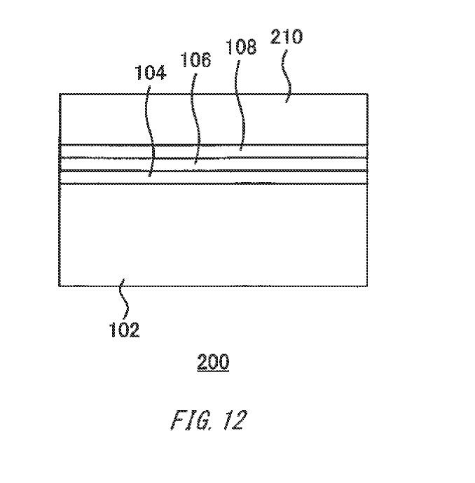

FIG. 12 is a cross-sectional view illustrating a semiconductor wafer 200. The semiconductor wafer 200 in the present fourth embodiment is similar to the semiconductor wafer 100 in the first embodiment, except that the semiconductor wafer 200 has a fourth semiconductor crystal layer 210. Accordingly, overlapping description is omitted.

The material of the fourth semiconductor crystal layer 210 is similar to that of the second semiconductor crystal layer 106. However, the fourth semiconductor crystal layer 210 constitutes hetero-junction together with the third semiconductor crystal layer 108, and is to be utilized as an active layer of a semiconductor device. Note that the method for manufacturing the fourth semiconductor crystal layer 210 is similar to the method for manufacturing the second semiconductor crystal layer 106.

That is, the semiconductor wafer 200 further has the fourth semiconductor crystal layer 210, and the semiconductor crystal layer forming wafer 102, the first semiconductor crystal layer 104, the second semiconductor crystal layer 106, the third semiconductor crystal layer 108, and the fourth semiconductor crystal layer 210 are positioned in the order of the semiconductor crystal layer forming wafer 102, the first semiconductor crystal layer 104, the second semiconductor crystal layer 106, the third semiconductor crystal layer 108, and the fourth semiconductor crystal layer 210. Both the etching rate of the first semiconductor crystal layer 104 by a first etching agent and the etching rate of the third semiconductor crystal layer 108 by the first etching agent are higher than the etching rate of the fourth semiconductor crystal layer 210 by the first etching agent. Also, both the etching rate of the first semiconductor crystal layer 104 by the second etching agent and the etching rate of the third semiconductor crystal layer 108 by the second etching agent are lower than the fourth semiconductor crystal layer 210 by the second etching agent. In the present example, the etching rate of the second semiconductor crystal layer 106 and the etching rate of the fourth semiconductor crystal layer 210 are equivalent to each other irrespective of the etching agent.

The semiconductor crystal layer forming wafer 102 may be made of InP, the first semiconductor crystal layer 104 and the third semiconductor crystal layer 108 may be made of InGaAs or InAs, and the second semiconductor crystal layer 106 and the fourth semiconductor crystal layer 210 may be made of InP, for example. Alternatively, the semiconductor crystal layer forming wafer 102 may be made of GaAs or Ge, the first semiconductor crystal layer 104 and the third semiconductor crystal layer 108 may be made of SiGe, and the second semiconductor crystal layer 106 and the fourth semiconductor crystal layer 210 may be made of Ge, for example.

### Fifth Embodiment

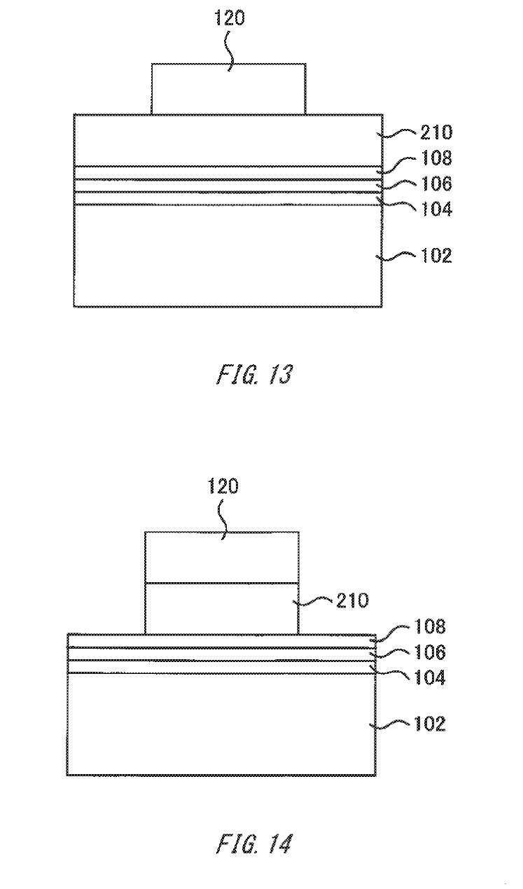

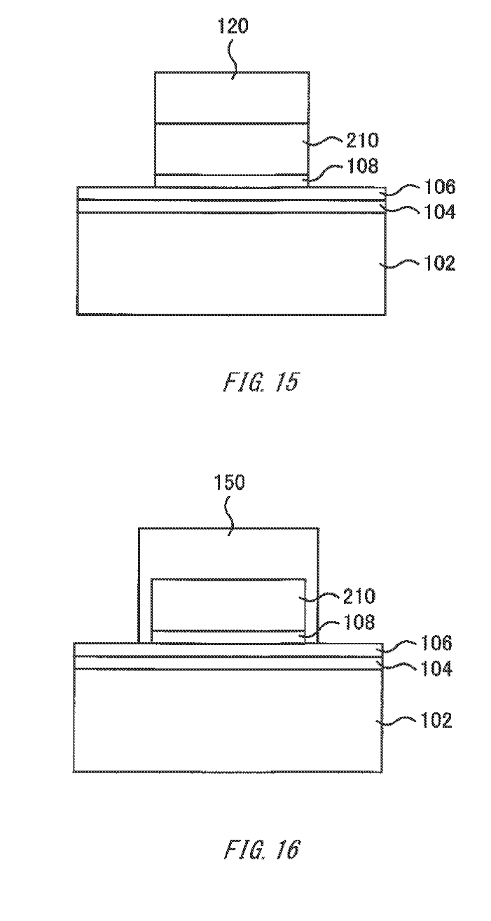

FIGS. 13 to 18 are cross-sectional views illustrating, in the order of steps, one example of a method for manufacturing a composite wafer by using the semiconductor wafer 200. As illustrated in FIG. 13, a pattern of the first cover layer 120 is formed on the semiconductor wafer 200, and as illustrated in FIG. 14, the fourth semiconductor crystal layer 210 is etched away by using the first cover layer 120 as a mask and by using the second etching agent (first etching step). As illustrated in FIG. 15, the third semiconductor crystal layer 108 is etched away by using, as a mask, the first cover layer 120 or the fourth semiconductor crystal layer 210 that has been patterned in the first etching step and using the first etching agent (second etching step). Note that the etching agent to be used in etching away the third semiconductor crystal layer 108 may not be the first etching agent. Also, the etching agent to be used in etching away the fourth semiconductor crystal layer 210 may not be the second etching agent.

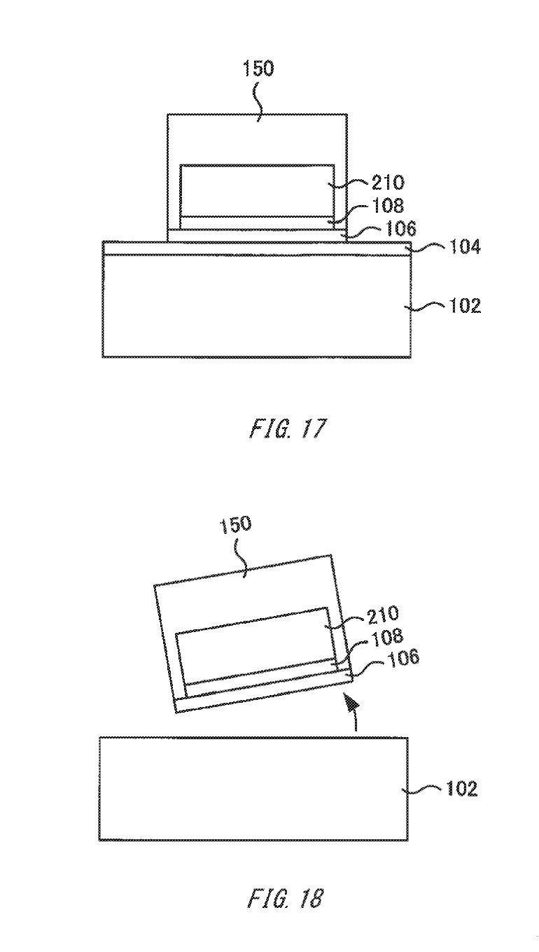

As illustrated in FIG. 16, a pattern of a fourth cover layer 150 to cover the fourth semiconductor crystal layer 210 that has been patterned in the first etching step and the third semiconductor crystal layer 108 that has been patterned in the second etching step is formed. As illustrated in FIG. 17, the second semiconductor crystal layer 106 is etched away by using the fourth cover layer 150 as a mask and by using the second etching agent (third etching step). Lastly, as illustrated in FIG. 18, the first semiconductor crystal layer 104 is removed by performing etching by using the first etching agent, and the second semiconductor crystal layer 106, the third semiconductor crystal layer 108, and the fourth semiconductor crystal layer 210 that are covered with the fourth cover layer 150 are separated from the semiconductor crystal layer forming wafer 102.

Because according to the above-mentioned method for manufacturing a composite wafer, even when the third semiconductor crystal layer 108 and the fourth semiconductor crystal layer 210 are made of different materials, and selection of the etching agent is significantly limited, the third semiconductor crystal layer 108 and the fourth semiconductor crystal layer 210 are surrounded by the fourth cover layer 150 and the second semiconductor crystal layer 106, the third semiconductor crystal layer 108 and the fourth semiconductor crystal layer 210, especially the third semiconductor crystal layer 108 that is easily corroded by the first etching agent, are never exposed to the first etching agent at the time of etching away the first semiconductor crystal layer 104. Also, because the fourth semiconductor crystal layer 210 is surrounded by the fourth cover layer 150 and the third semiconductor crystal layer 108, the fourth semiconductor crystal layer 210 that is easily corroded by the second etching agent is never exposed to the second etching agent at the time of etching away the second semiconductor crystal layer 106. Accordingly, a material that is similar to that of the first semiconductor crystal layer 104 can be used as the third semiconductor crystal layer 108, and an etching agent (first etching agent) can be selected without being limited by the material of the third semiconductor crystal layer 108 to form hetero-junction with the fourth semiconductor crystal layer 210. Accordingly, the degree of freedom of manufacturing a composite wafer is enhanced, and the manufacturing becomes easy. Note that as in the second embodiment, the transfer target wafer 220 can be applied to the fifth embodiment.

### Sixth Embodiment

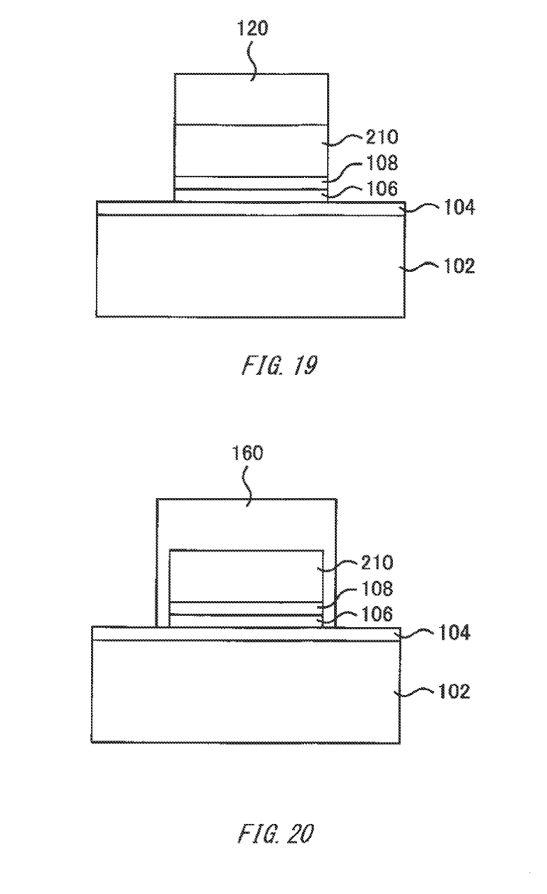

FIGS. 19 to 21 are cross-sectional views illustrating, in the order of steps, another example of a method for manufacturing a composite wafer by using the semiconductor wafer 200. The sixth embodiment is similar to the fifth embodiment up until the pattern of the first cover layer 120 is formed on the semiconductor wafer 200, and by using the first cover layer 120 as a mask, the fourth semiconductor crystal layer 210 and the third semiconductor crystal layer 108 are etched away by using the second etching agent and the first etching agent, respectively. In the present embodiment, as illustrated in FIG. 19, the second semiconductor crystal layer 106 is sequentially etched away by using the second etching agent (first etching step). Next, as illustrated in FIG. 20, a pattern of a fifth cover layer 160 to cover the fourth semiconductor crystal layer 210, the third semiconductor crystal layer 108, and the second semiconductor crystal layer 106 that have been patterned in the first etching step is formed. Furthermore, as illustrated in FIG. 21, the first semiconductor crystal layer 104 is removed by performing etching by using the first etching agent, and the second semiconductor crystal layer 106, the third semiconductor crystal layer 108, and the fourth semiconductor crystal layer 210 that are covered with the fifth cover layer 160 are separated from the semiconductor crystal layer forming wafer 102.

Effects similar to those of the fifth embodiment can be attained in the method for manufacturing a composite wafer like this. Note that as in the second embodiment, the transfer target wafer 220 can be applied to the sixth embodiment.

Note that, in the above-mentioned embodiment, a plurality of the set of the first semiconductor crystal layer 104, the second semiconductor crystal layer 106, and the third semiconductor crystal layer 108, or a plurality of the set of the first semiconductor crystal layer 104, the second semiconductor crystal layer 106, the third semiconductor crystal layer 108, and the fourth semiconductor crystal layer 210 may be repeatedly laminated on the semiconductor crystal layer forming wafer 102. In this case, the above-mentioned method for manufacturing a composite wafer may be applied to the uppermost set of layers to transfer the second semiconductor crystal layer 106, the third semiconductor crystal layer 108, and the like onto the transfer target wafer 220, and subsequently, transfer of the second semiconductor crystal layer 106, the third semiconductor crystal layer 108, and the like may be performed similarly on the second uppermost set. Thereby, the epitaxial growth step on the semiconductor crystal layer forming wafer 102 can be shortened.

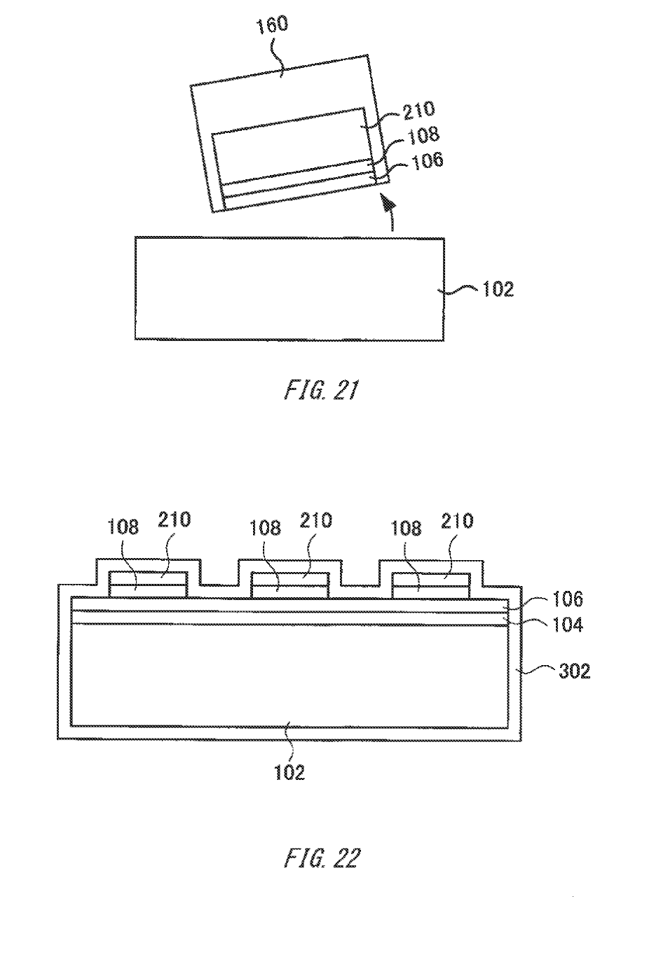

Also, in the above-mentioned embodiment, the second cover layer 130, the third cover layer 140, the fourth cover layer 150, and the fifth cover layer 160 respectively may cover the third semiconductor crystal layer 108 or the like depending their aspects, and may cover the back surface and side surface of the semiconductor crystal layer forming wafer 102. For example, an example in which, in the fifth embodiment, the fourth cover layer 150 covers the back surface and side surface of the semiconductor crystal layer forming wafer 102 is described. FIGS. 22 to 25 are cross-sectional views illustrating, in the order of steps, still another example of a method for manufacturing a composite wafer by using the semiconductor wafer 200.

After patterning the fourth semiconductor crystal layer 210 and the third semiconductor crystal layer 108 by dry etching, as illustrated in FIG. 22, a cover layer 302 (corresponding to the fourth cover layer 150) to cover the fourth semiconductor crystal layer 210 and the third semiconductor crystal layer 108 and cover the back surface and side surface of the semiconductor crystal layer forming wafer 102 is formed. In the present example, the fourth semiconductor crystal layer 210 and the third semiconductor crystal layer 108 are divided into a plurality of divided pieces. Also, the cover layer 302 in the present example is formed also on the exposed front surface of the second semiconductor crystal layer 106. Examples of the cover layer 302 include an Al₂O₃ layer that is formed by ALD (ALD-Al₂O₃ layer), for example. Examples of the growth temperature of the ALD-Al₂O₃ layer include 300° C., and examples of the raw material gas include TMA (trimethylaluminum) and water (H₂O). The thickness of the ALD-Al₂O₃ layer may be 33 nm. Post-annealing may be performed on the ALD-Al₂O₃ layer after being formed.

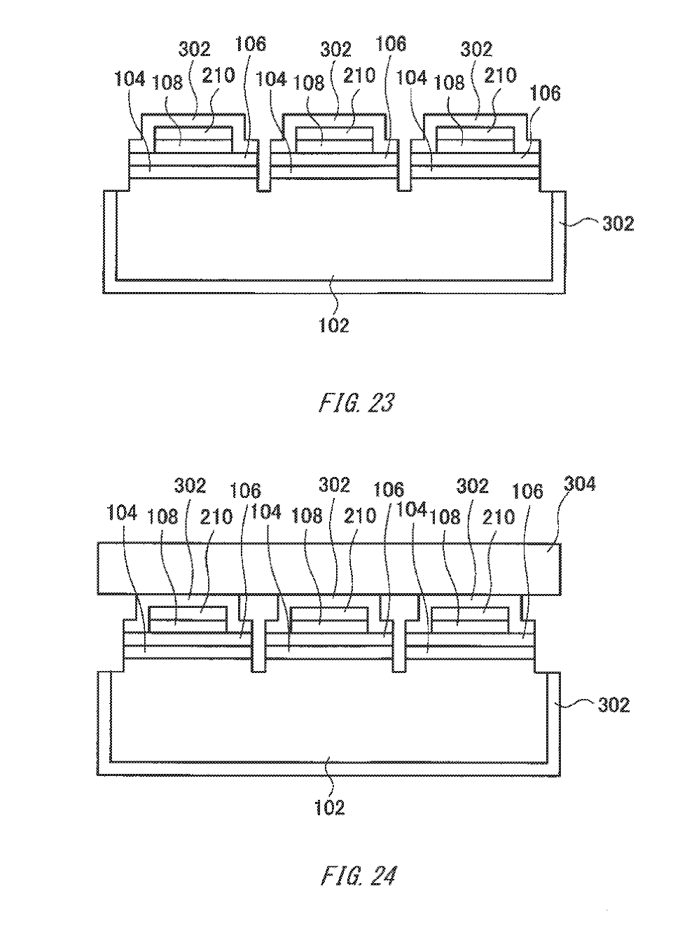

As illustrated in FIG. 23, a pattern of the cover layer 302 is formed to include the patterns of the fourth semiconductor crystal layer 210 and the third semiconductor crystal layer 108. In the present example, portions of the cover layer 302 that are not covering the fourth semiconductor crystal layer 210 and the third semiconductor crystal layer 108 are etched away to form the pattern of the cover layer 302. Then, the second semiconductor crystal layer 106 and the first semiconductor crystal layer 104 are etched away by using the cover layer 302 as a mask. As illustrated in FIG. 24, after bonding the transfer target wafer 304, as illustrated in FIG. 25, the first semiconductor crystal layer 104 is removed by performing etching (for example, wet etching) by using the first etching agent; thereby, the third semiconductor crystal layer 108 and the fourth semiconductor crystal layer 210 that are covered with the cover layer 302 and the second semiconductor crystal layer 106 can be separated from the semiconductor crystal layer forming wafer 102.

Note that the method of forming the cover layer 302 illustrated in FIGS. 22 to 25 can be applied to any of the above-mentioned embodiments. According to the method illustrated in FIGS. 22 to 25, the back surface and side surface of the semiconductor crystal layer forming wafer 102 are covered with the cover layer 302, and the semiconductor crystal layer forming wafer 102 is thus protected.

### Seventh Embodiment

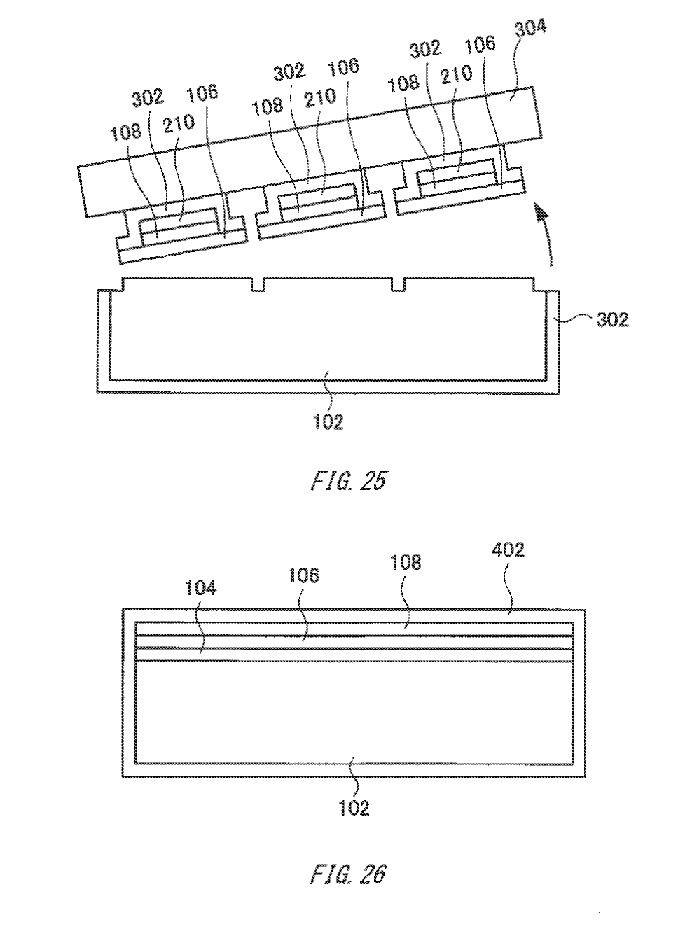

FIGS. 26 to 30 are cross-sectional views illustrating, in the order of steps, still another example of a method for manufacturing a composite wafer by using the semiconductor wafer 100. The method in the seventh embodiment is described as an example in which even the second semiconductor crystal layer 106 that is made of a material that does not have an etching selection ratio with respect to the semiconductor crystal layer forming wafer 102 can be used as a sacrificial layer because the back surface and side surface of the semiconductor crystal layer forming wafer 102 are covered with a cover layer 402, and the front surface of the semiconductor crystal layer forming wafer 102 is covered with the first semiconductor crystal layer 104. In the present example, both the etching rate of the semiconductor crystal layer forming wafer 102 by the second etching agent and the etching rate of the second semiconductor crystal layer 106 by the second etching agent are higher than both the etching rate of the first semiconductor crystal layer 104 by the second etching agent and the etching rate of the third semiconductor crystal layer 108 by the second etching agent.

As illustrated in FIG. 26, the entire surface of the semiconductor wafer 100 is covered with the cover layer 402. Examples of the cover layer 402 include an Al₂O₃ layer (ALD-Al₂O₃ layer) that is formed by using ALD, for example. Examples of the growth temperature of the ALD-Al₂O₃ layer include 300° C., and examples of the raw material gas include TMA (trimethylaluminum) and water (H₂O). Examples of the thickness of the ALD-Al₂O₃ layer include 33 nm, for example. Post-annealing may be performed on the ALD-Al₂O₃ layer after being formed.

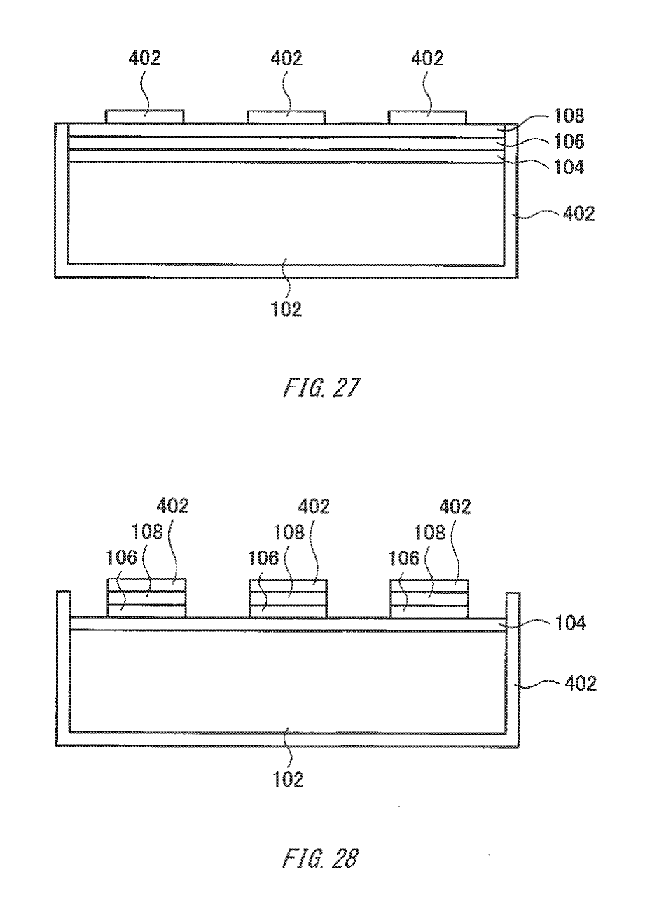

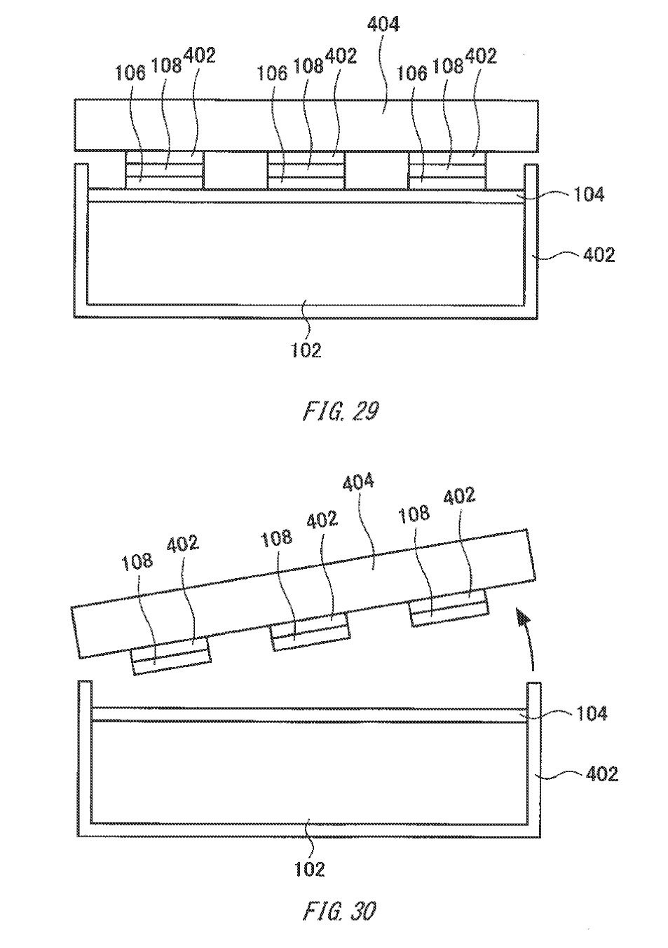

As illustrated in FIG. 27, the cover layer 402 is patterned on the third semiconductor crystal layer 108, and as illustrated in FIG. 28, the third semiconductor crystal layer 108 is etched away by using the patterned cover layer 402 as a mask. As illustrated in FIG. 28, after etching away the third semiconductor crystal layer 108 and before bonding the transfer target wafer 404, the second semiconductor crystal layer 106 may be etched away by dry etching, for example. As illustrated in FIG. 29, after bonding the transfer target wafer 404, as illustrated in FIG. 30, the second semiconductor crystal layer 106 is removed by performing etching (for example, wet etching) by using the second etching agent, and the third semiconductor crystal layer 108 is separated from the semiconductor crystal layer forming wafer 102. Even when the semiconductor crystal layer forming wafer 102 is one that can be etched away by the second etching agent, the semiconductor crystal layer forming wafer 102 is protected by the cover layer 402 and the first semiconductor crystal layer 104, and thus is never exposed to the second etching agent, but is protected from etching.

(Example of Seventh Embodiment)

A 100-nm In_{0.53}Ga_{0.47}As layer (the first semiconductor crystal layer 104 to serve as a cover layer), a 100-nm InP layer (the second semiconductor crystal layer 106 to serve as a sacrificial layer), and a 200-nm In_{0.53}Ga_{0.47}As layer (the third semiconductor crystal layer 108 to serve as an active layer) were sequentially formed, by epitaxial growth by low-pressure MOCVD, on a 2-inch InP wafer which is the semiconductor crystal layer forming wafer 102 to fabricate a multilayer wafer. Thereafter, the multilayer wafer was introduced into an ALD device, and was coated with Al₂O₃ (the cover layer 402) of approximately 33 nm by ALD. The deposition conditions of ALD-Al₂O₃ were as follows: 300° C.; 300 cycles; the aluminum material was TMA (trimethylaluminum); and the oxidant was H₂O. Uniform Al₂O₃ could be deposited on the front surface/back surface/side surface of the multilayer wafer by using ALD. Here, to enhance the coating effect of the ALD-Al₂O₃ layer (resistance against an acid solution), post-annealing in nitrogen was performed at 600° C. for 90 seconds.

Note that the coating effect of the Al₂O₃ layer was separately confirmed with an InP wafer (wafer on which the semiconductor crystal layer was not grown epitaxially). That is, after Al₂O₃ was coated on the InP wafer under the same conditions as the above-mentioned ones, the InP wafer was immersed in hydrochloric acid, but etching did not proceed even after the elapse of five hours or longer, and the state before the immersion was maintained.

In the present example, a positive resist film having a line/space pattern (LS pattern) of 300-μm line width/200-μm pitch was formed on the multilayer wafer, and the ALD-Al₂O₃ layer was etched away by performing dry etching by using the resist film as a mask and by using CHF₃ gas. The resist film was removed by acetone washing and ashing, the step that was formed by etching was measured by using a contact-type step gauge to obtain a measurement of approximately 40 nm. This is slightly larger than the designed value of the Al₂O₃ layer which was 33 nm, but this is because a part of the In_{0.53}Ga_{0.47}As layer that was lying under the Al₂O₃ layer was etched away. Next, the In_{0.53}Ga_{0.47}As layer was subjected to an etching process by using the patterned Al₂O₃ layer as a mask and by using phosphoric acid:hydrogen peroxide solution (3:1:50). Because this etchant does not dissolve InP almost at all, the etching stopped when it reached the InP layer (the sacrificial layer, the second semiconductor crystal layer 106). The Al₂O₃/In_{0.53}Ga_{0.47}As layer (the active layer, the third semiconductor crystal layer 108) was divided into a plurality of divided pieces by the etching. Next, a process to bond the Al₂O₃ layer of the processed multilayer wafer front surface and a 4-inch Si wafer was performed. By irradiating the front surface of the Al₂O₃ layer and the front surface of the Si wafer which was a transfer target wafer with argon ion beam, the front surfaces were activated. Thereafter, the front surface of the Al₂O₃ layer and the front surface of the Si wafer were caused to face each other, and the processed multilayer wafer and the Si wafer were bonded with each other. The attachment under pressure was performed at normal temperature.

Lastly, an etching solution was introduced into a cavity formed by grooves between adjacent divided pieces of the Al₂O₃/In_{0.53}Ga_{0.47}As layer, the InP layer (the second semiconductor crystal layer 106) which was the sacrificial layer was removed by etching, and the multilayer wafer and the Si wafer were separated from each other in a state that the Al₂O₃/In_{0.53}Ga_{0.47}As layer was left on the Si wafer. The etching of the InP layer was performed by immersing the side surface of the bonded wafer into a 23° C. etching solution whose HCl concentration was 10% by mass (10% hydrogen chloride solution), introducing the etching solution into the cavity by the capillary phenomenon, and maintaining this state. The In_{0.53}Ga_{0.47}As layer is not dissolved by the above-mentioned HCl etchant almost at all. Also, the InP wafer was protected by the Al₂O₃ layer and the In_{0.53}Ga_{0.47}As layer (the cover layer), and thus was never exposed to the HCl etchant, but was protected. In the above-described manner, a semiconductor crystal layer forming wafer having a 200-nm thickness and 300/200-μm LS pattern In_{0.53}Ga_{0.47}As layer on the 4-inch Si wafer was obtained.

When it is described in the present specification that a second element is located “on” a first element such as a layer or a wafer, such description includes a case where the second element is disposed directly on the first element, and also a case where the second element is disposed indirectly on the first element with another element being interposed between the second element and the first element. When the second element is formed “on” the first element also, similarly, the second element may be formed directly or indirectly on the first element. Also, the terms like “on” or “under” that indicate directions indicate relative directions within a semiconductor wafer, a composite wafer, and a device, and may not indicate absolute directions with respect to an external reference surface such as the ground.

What is claimed is:

1. A semiconductor wafer comprising, on a semiconductor crystal layer forming wafer, a first semiconductor crystal layer, a second semiconductor crystal layer, and a third semiconductor crystal layer, the semiconductor crystal layer forming wafer, the first semiconductor crystal layer, the second semiconductor crystal layer, and the third semiconductor crystal layer being positioned in the order of the semiconductor crystal layer forming wafer, the first semiconductor crystal layer, the second semiconductor crystal layer, and the third semiconductor crystal layer, wherein
both the etching rate of the first semiconductor crystal layer by a first etching agent and the etching rate of the third semiconductor crystal layer by the first etching agent are higher than the etching rate of the second semiconductor crystal layer by the first etching agent, and
both the etching rate of the first semiconductor crystal layer by a second etching agent and the etching rate of the third semiconductor crystal layer by the second etching agent are lower than the etching rate of the second semiconductor crystal layer by the second etching agent.

2. The semiconductor wafer according to claim 1, further comprising a fourth semiconductor crystal layer, the semiconductor crystal layer forming wafer, the first semiconductor crystal layer, the second semiconductor crystal layer, the third semiconductor crystal layer, and the fourth semiconductor crystal layer being positioned in the order of the semiconductor crystal layer forming wafer, the first semiconductor crystal layer, the second semiconductor crystal layer, the third semiconductor crystal layer, and the fourth semiconductor crystal layer, wherein
both the etching rate of the first semiconductor crystal layer by the first etching agent and the etching rate of the third semiconductor crystal layer by the first etching agent are higher than the etching rate of the fourth semiconductor crystal layer by the first etching agent, and
both the etching rate of the first semiconductor crystal layer by the second etching agent and the etching rate of the third semiconductor crystal layer by the second etching agent are lower than the etching rate of the fourth semiconductor crystal layer by the second etching agent.

3. The semiconductor wafer according to claim 1, wherein
the etching rate of the semiconductor crystal layer forming wafer by the first etching agent is equivalent to the etching rate of the second semiconductor crystal layer by the first etching agent, and
the etching rate of the semiconductor crystal layer forming wafer by the second etching agent is equivalent to the etching rate of the second semiconductor crystal layer by the second etching agent.

4. The semiconductor wafer according to claim 1, wherein the semiconductor crystal layer forming wafer is made of InP, the first semiconductor crystal layer and the third semiconductor crystal layer are made of InGaAs or InAs, and the second semiconductor crystal layer is made of InP.

5. The semiconductor wafer according to claim 2, wherein the semiconductor crystal layer forming wafer is made of InP, the first semiconductor crystal layer and the third semiconductor crystal layer are made of InGaAs or InAs, and the second semiconductor crystal layer and the fourth semiconductor crystal layer are made of InP.

6. The semiconductor wafer according to claim 4, wherein
the third semiconductor crystal layer has a semiconductor laminate structure, and
the semiconductor laminate structure consists of a plurality of semiconductor layers that lattice-match or pseudo-lattice-match InP.

7. The semiconductor wafer according to claim 1, wherein the semiconductor crystal layer forming wafer is made of GaAs or Ge, the first semiconductor crystal layer and the third semiconductor crystal layer are made of SiGe, and the second semiconductor crystal layer is made of Ge.

8. The semiconductor wafer according to claim 2, wherein the semiconductor crystal layer forming wafer is made of GaAs or Ge, the first semiconductor crystal layer and the third semiconductor crystal layer are made of SiGe, and the second semiconductor crystal layer and the fourth semiconductor crystal layer are made of Ge.

9. A method for manufacturing a semiconductor wafer comprising forming, on a semiconductor crystal layer forming wafer, a first semiconductor crystal layer, a second semiconductor crystal layer, and a third semiconductor crystal layer in the order of the first semiconductor crystal layer, the second semiconductor crystal layer, and the third semiconductor crystal layer by epitaxial growth, wherein
the first semiconductor crystal layer, the second semiconductor crystal layer, and the third semiconductor crystal layer are such that both the etching rate of the first semiconductor crystal layer by a first etching agent and the etching rate of the third semiconductor crystal layer by the first etching agent are higher than the etching rate of the second semiconductor crystal layer by the first etching agent, and both the etching rate of the first semiconductor crystal layer by a second etching agent and the etching rate of the third semiconductor crystal layer by the second etching agent are lower than the etching rate of the second semiconductor crystal layer by the second etching agent.

10. A method for manufacturing a semiconductor wafer comprising forming, on a semiconductor crystal layer forming wafer, a first semiconductor crystal layer, a second semiconductor crystal layer, a third semiconductor crystal layer, and a fourth semiconductor crystal layer in the order of the first semiconductor crystal layer, the second semiconductor crystal layer, the third semiconductor crystal layer, and the fourth semiconductor crystal layer by epitaxial growth, wherein
the first semiconductor crystal layer, the second semiconductor crystal layer, the third semiconductor crystal layer, and the fourth semiconductor crystal layer are such that both the etching rate of the first semiconductor crystal layer by a first etching agent and the etching rate of the third semiconductor crystal layer by the first etching agent are higher than both the etching rate of the second semiconductor crystal layer by the first etching agent and the etching rate of the fourth semiconductor crystal layer by the first etching agent, and both the etching rate of the first semiconductor crystal layer by a second etching agent and the etching rate of the third semiconductor crystal layer by the second etching agent are lower than both the etching rate of the second semiconductor crystal layer by the second etching agent and the etching rate of the fourth semiconductor crystal layer by the second etching agent.

11. A method for manufacturing a composite wafer, the method comprising:
forming a pattern of a first cover layer on the semiconductor wafer according to claim 1;
performing first etching to etch away the third semiconductor crystal layer by using the first cover layer as a mask;
forming a pattern of a second cover layer to cover the third semiconductor crystal layer patterned by the first etching;
performing second etching to etch away the second semiconductor crystal layer by using the second cover layer as a mask and by using the second etching agent; and
removing the first semiconductor crystal layer by performing etching by using the first etching agent, and separating, from the semiconductor crystal layer forming wafer, the second semiconductor crystal layer and the third semiconductor crystal layer that are covered with the second cover layer.

12. The method for manufacturing a composite wafer according to claim 11, wherein the first etching includes etching away the third semiconductor crystal layer by using the first etching agent.

13. The method for manufacturing a composite wafer according to claim 11, wherein the second cover layer covers the third semiconductor crystal layer, and covers the back surface and side surface of the semiconductor crystal layer forming wafer.

14. A method for manufacturing a composite wafer, the method comprising:
forming a pattern of a first cover layer on the semiconductor wafer according to claim 1,
performing first etching to etch away the third semiconductor crystal layer by using the first cover layer as a mask;
performing second etching to etch away the second semiconductor crystal layer by using, as a mask, the first cover layer or the third semiconductor crystal layer patterned in the first etching and using the second etching agent;
forming a pattern of a third cover layer to cover the third semiconductor crystal layer patterned in the first etching and the second semiconductor crystal layer patterned in the second etching; and
removing the first semiconductor crystal layer by performing etching by using the first etching agent, and separating, from the semiconductor crystal layer forming wafer, the second semiconductor crystal layer and the third semiconductor crystal layer that are covered with the third cover layer.

15. The method for manufacturing a composite wafer according to claim 14, wherein the third cover layer covers the third semiconductor crystal layer and the second semiconductor crystal layer, and covers the back surface and side surface of the semiconductor crystal layer forming wafer.

16. A method for manufacturing a composite wafer, the method comprising:
forming a pattern of a first cover layer on the semiconductor wafer according to claim 2;
performing first etching to etch away the fourth semiconductor crystal layer by using the first cover layer as a mask;
performing second etching to etch away the third semiconductor crystal layer by using, as a mask, the first cover layer or the fourth semiconductor crystal layer patterned by the first etching;
forming a pattern of a fourth cover layer to cover the fourth semiconductor crystal layer patterned in the first etching and the third semiconductor crystal layer patterned in the second etching;
performing third etching to etch away the second semiconductor crystal layer by using the fourth cover layer as a mask and by using the second etching agent; and
removing the first semiconductor crystal layer by performing etching by using the first etching agent, and separating, from the semiconductor crystal layer forming wafer, the second semiconductor crystal layer, the third semiconductor crystal layer, and the fourth semiconductor crystal layer that are covered with the fourth cover layer.

17. The method for manufacturing a composite wafer according to claim 16, wherein
the first etching includes etching away the fourth semiconductor crystal layer by using the second etching agent, and
the second etching includes etching away the third semiconductor crystal layer by using the first etching agent.

18. The method for manufacturing a composite wafer according to claim 16, wherein the fourth cover layer covers the fourth semiconductor crystal layer and the third semiconductor crystal layer, and covers the back surface and side surface of the semiconductor crystal layer forming wafer.

19. A method for manufacturing a composite wafer, the method comprising:
forming a pattern of a first cover layer on the semiconductor wafer according to claim 2;
performing first etching to etch away the fourth semiconductor crystal layer and the third semiconductor crystal layer by using the first cover layer as a mask and to further etch away the second semiconductor crystal layer by using the second etching agent;
forming a pattern of a fifth cover layer to cover the fourth semiconductor crystal layer, the third semiconductor crystal layer, and the second semiconductor crystal layer that are patterned in the first etching; and
removing the first semiconductor crystal layer by performing etching by using the first etching agent, and separating, from the semiconductor crystal layer forming wafer, the second semiconductor crystal layer, the third semiconductor crystal layer, and the fourth semiconductor crystal layer that are covered with the fifth cover layer.

20. The method for manufacturing a composite wafer according to claim 19, wherein the fifth cover layer covers the fourth semiconductor crystal layer, the third semiconductor crystal layer, and the second semiconductor crystal layer, and covers the back surface and side surface of the semiconductor crystal layer forming wafer.

21. The method for manufacturing a composite wafer according to claim 11, the method further comprising:
prior to the separation, bonding the semiconductor wafer and a transfer target wafer, with the front surface of the semiconductor wafer on which the third semiconductor crystal layer is formed being caused to face the front surface of the transfer target wafer; and
during the separation, separating the semiconductor wafer and the transfer target wafer in a state that a semiconductor crystal layer including the second semiconductor crystal layer and the third semiconductor crystal layer is left on the transfer target wafer.

22. A method for manufacturing a composite wafer, the method comprising:
forming a sixth cover layer to cover the entire surface of the semiconductor wafer according to claim 1,
patterning and removing a part of the sixth cover layer on the third semiconductor crystal layer;
etching away the third semiconductor crystal layer by using the sixth cover layer on the third semiconductor crystal layer as a mask; and
removing the second semiconductor crystal layer by performing etching by using the second etching agent, and separating the third semiconductor crystal layer from the semiconductor crystal layer forming wafer that is covered with the sixth cover layer and the first semiconductor crystal layer.

23. The method for manufacturing a composite wafer according to claim 22, the method further comprising:
after etching away the third semiconductor crystal layer and prior to the separation, bonding the semiconductor wafer and a transfer target wafer, with the front surface of the third semiconductor crystal layer being caused to face the front surface of the transfer target wafer; and
during the separation, separating the semiconductor wafer and the transfer target wafer in a state that the third semiconductor crystal layer is left on the transfer target wafer.

24. The method for manufacturing a composite wafer according to claim 23, further comprising, after etching away the third semiconductor crystal layer and prior to the bonding, etching away the second semiconductor crystal layer by using the sixth cover layer as a mask and by using the second etching agent.

25. A method for manufacturing a composite wafer by using a semiconductor wafer having, on a semiconductor crystal layer forming wafer, a first semiconductor crystal layer, a second semiconductor crystal layer, and a third semiconductor crystal layer, the semiconductor crystal layer forming wafer, the first semiconductor crystal layer, the second semiconductor crystal layer, and the third semiconductor crystal layer being positioned in the order of the semiconductor crystal layer forming wafer, the first semiconductor crystal layer, the second semiconductor crystal layer, and the third semiconductor crystal layer,
both the etching rate of the semiconductor crystal layer forming wafer by a second etching agent and the etching rate of the second semiconductor crystal layer by the second etching agent being higher than both the etching rate of the first semiconductor crystal layer by the second etching agent and the etching rate of the third semiconductor crystal layer by the second etching agent, the method comprising
forming a sixth cover layer to cover the entire surface of the semiconductor wafer;
patterning and removing a part of the sixth cover layer on the third semiconductor crystal layer;
etching away the third semiconductor crystal layer by using the sixth cover layer on the third semiconductor crystal layer as a mask; and
removing the second semiconductor crystal layer by performing etching by using the second etching agent, and separating the third semiconductor crystal layer from the semiconductor crystal layer forming wafer that is covered with the sixth cover layer and the first semiconductor crystal layer.
